(19) United States
(12) Patent Application Publication
(10) Pub. No.: US 2018/0288906 A1
(43) Pub. Date: Oct. 4, 2018

(54) AN IMMERSION COOLING SYSTEM

(71) Applicant: ICEOTOPE LIMITED, ST PETER PORT (GG)

(72) Inventors: Peter Hopton, South Yorkshire (GB); Keith Deakin, South Yorkshire (GB); Jason Bent, South Yorkshire (GB); Neil Edmunds, South Yorkshire (GB); David Amos, South Yorkshire (GB)

(21) Appl. No.: 15/764,605

(22) PCT Filed: Oct. 3, 2016
(86) PCT No.: PCT/GB2016/053070

§ 371 Date: Mar. 29, 2018

(30) Foreign Application Priority Data
Oct. 1, 2015 (GB) 1517385.9

(51) Int. Cl. H05K 7/20; H05K 7/14

(52) U.S. Cl. CPC H05K 7/20772; H05K 7/20236; H05K 7/1492; H05K 7/203; H05K 7/20263; H05K 7/20245; H05K 7/20809; H05K 7/209

(57) ABSTRACT

A cooling system for cooling of a heat generating electrical component, in particular to reduce the likelihood of overheating of electrical components or chemical breakdown of coolant fluid. The cooling system has a coolant liquid to absorb excess energy from the heat generating electrical component, the coolant liquid having an energy input threshold above which chemical breakdown of the coolant liquid occurs. A cooling module defines a volume containing the coolant liquid, wherein the heat generating electrical component is mounted within the volume and immersed in the coolant liquid. A power input is arranged to supply power into the cooling module to the heat generating electrical component, and a power regulator is provided external to the volume of the cooling module and connected to the power input so as to regulate the power supplied into the cooling module. Cooling systems are also described having coolant liquid comprising dissolved oxygen, having at least one element arranged within the volume comprising aluminium and/or aluminium oxide, and/or having a sealed volume with at least one seal which opens at a predetermined pressure or temperature corresponding to a temperature below the temperature at which the coolant liquid breaks down.

### FIELD OF THE INVENTION

The invention relates to an immersion cooling system providing improved safety during operation. The cooling system improves safety by regulating the power input to electrical components immersed in a coolant liquid within the cooling system, and also by providing a variety of mechanisms by which the overheating of components can be halted and the products of the chemical breakdown of the coolant fluid neutralised. In particular, the invention is applicable for use in cooling of electrical computer components, for example motherboards, processors or memory modules.

### BACKGROUND TO THE INVENTION

Many types of electrical component generate heat during operation. In particular, electrical computer components such as motherboards, central processing units (CPUs) and memory modules may dissipate substantial amounts of heat when in use. Heating of the electrical components to high temperatures can cause damage, affect performance or cause a safety hazard. Accordingly, substantial efforts have been undertaken to find efficient, high performance systems for cooling electrical components effectively and safely.

One type of cooling system uses liquid cooling. Although different liquid cooling assemblies have been demonstrated, in general the electrical components are immersed in a coolant liquid so as to provide a large surface area for heat exchange between the heat generating electrical components and the coolant. Heat is then removed from the coolant via convection and conduction to a heat exchanger or similar cooling arrangement.

Within normal operating conditions for temperature, current and voltage, most liquid cooling systems will operate safely without risk to the user. However, when a fault occurs the heat generated by the electrical components can increase, sometimes quickly. Under this scenario, transfer of heat to the coolant liquid can occur at a rate faster than the dissipation of that heat from the cooling system. As a result, the temperature of the coolant liquid increases and, at a certain temperature, chemical breakdown of the coolant can take place. Chemical breakdown products of the coolant can present significant dangers to the health of the user if ingested due to their harmful, toxic or irritant nature.

Materials used for coolant fluid may include oils (for instance, either natural oils or synthetic oils) and well as fluorine based materials (such as fluoro-octane, hydrofluoroether, hydrofluorolefin, perfluoroketone and perfluoropolyether). Thermal breakdown of even small quantities of fluorine based fluids may result in quantities of Hydrofluoric acid (HF) or perfluoroisobutene (PFIB) being generated. If released from the cooling system, these chemicals can cause considerable damage to human health.

Current systems have aimed to overcome these safety issue by implementation of fuses or circuit breakers to shut off the power to the electrical devices within the cooling system in the event that a large power is drawn by an electrical component. However, in systems in which a very large power is available (such as in power conversion applications), even in the short time taken for the circuit breaker to trip or for a fuse to break and the power to be turned off, the coolant can undergo chemical breakdown to produce hazardous amounts of chemical breakdown product.

U.S. Pat. No. 6,215,166 considers an apparatus for controlling the power delivered to an electronic device within a liquid spray cooling system. In operation, the device is sprayed with a coolant liquid which evaporates from the surface of the device to remove excess heat. A power input lead connected directly to the device is configured to melt or to change electrical characteristics as a result of an increase in temperature of the power input lead. However, the apparatus relies on heating of the power input leads in the vicinity of the device and a supply of large powers to the power input leads within the enclosed cooling system. As such, there is still a possibility that some small amounts of chemical breakdown of the coolant fluid could occur. Exposure to a user of the cooling system to even trace amounts of coolant breakdown products such as PFIB and HF may be hazardous to their health.

Therefore, an immersion cooling system is required which improves the safety of an immersion cooling environment.

### SUMMARY OF THE INVENTION

Against this background, there is described a cooling system comprising a cooling module in which at least one heat generating electrical component is housed, a power input to the cooling module, and a power regulator arranged external to the cooling module to control and stabilise the power provided to the at least one heat generating electrical component. The heat generating electrical components are immersed in a coolant fluid contained within the cooling module.

The power regulator manages and regulates the electrical energy passed through the power input and into the cooling module by stabilising the power level available to be input to the cooling module. In this way, the power regulator isolates the high powers available to the cooling system from the immersion cooling environment. As a result, the power regulator restricts or limits the excess energy available to the heat generating components to be dissipated to the coolant fluid. Thus, the power regulator can be used to prevent excessive heating of the coolant fluid. Consequently, the likelihood is reduced of the coolant reaching a temperature at which chemical breakdown could occur. Nevertheless, in the event that excessive heating of the coolant does occur, methods of neutralising the hazardous chemical breakdown products and preventing runaway temperature increase of the coolant are also provided. In some cases, the power regulator may provide overcurrent protection, whereby if the current exceeds a particular input value, then the power regulator (or overcurrent protector) shuts off all power at the cooling system.

According to a first aspect of the invention there is provided a cooling system for cooling of a heat generating electrical component, comprising a coolant liquid to absorb excess energy from the heat generating electrical component, wherein the coolant liquid has an energy input threshold above which chemical breakdown of the coolant liquid occurs; a cooling module defining a volume containing the coolant liquid, the heat generating electrical component mounted within the volume and immersed in the coolant liquid; a power input arranged to supply power into the cooling module to energise the heat generating electrical component; and a power regulator, external to the volume of the cooling module and connected to the power input, the power regulator configured to regulate the power supplied into the cooling module such that the excess energy is maintained below the energy input threshold.

In other words, for a given system the coolant fluid can absorb or receive a specific maximum energy before chemical breakdown occurs. If the energy transferred from the heat generating components to the coolant fluid is transferred at a rate faster than the energy dissipated from the cooling apparatus (for example, by transfer of a heat from the coolant to a heat exchanger), then the energy stored by the coolant increases. The stored energy increases the temperature and pressure of the coolant within the cooling module. The coolant fluid will change phase from liquid to gas at a specific temperature, and chemical breakdown of the fluid will occur at a still higher temperature. The power regulator manages or regulates the power (or rate of energy input) into the cooling module, to maintain the coolant fluid at a temperature significantly below the temperature (or energy threshold) required for chemical breakdown of the coolant fluid.

Beneficially, the power regulator limits the power in the cooling module available to heat generating components in the immersion environment. Therefore, the excess energy at the heat generating component is limited, even in the event the heat generating component experiences a fault. Accordingly the amount of heat energy that can be transferred to the coolant liquid within a specific period of time is limited. The power regulator may be used to limit the power supplied to the heat generating component to a level at which the excess heat energy from the heat generating components can be removed from the cooling module by the cooling system, when under normal operation.

The heat generating electrical component may be any type of electrical component, and in particular may be a computer component. For example, the heat generating electrical component may form part of a CPU or be used for data storage. There may be more than one heat generating electrical component mounted within the cooling module, and reference to “a” heat generating electrical component herein should be interpreted to mean “at least one” heat generating electrical component.

The cooling module may be any type of cooling module suitable for immersion cooling. For example, the cooling module may comprise a sealable module defining a volume for containing the coolant liquid, the heat generating electrical component mounted within the volume. A thermal interface may be arranged at the cooling module, through which heat can be transferred out of the volume. In particular, a heat exchanger may be configured to receive heat from the volume, transferred through the thermal interface. The heat exchanger may provide a circulatory system or other system for transport of the heat away from the cooling module. A surface of the thermal interface may be an inner surface of the sealable module, such that the surface of the thermal interface is at least one of the surfaces defining the volume.

The cooling module may be configured to allow single phase (i.e. liquid) immersion cooling of the electrical components and any components mounted within the cooling module. Heat is removed from the vicinity of the heat generating electrical components due to convection currents within the coolant, which transport heat to the thermal interface through which heat is transferred to the heat exchanger. In some circumstances, the cooling module may be configured to allow two-phase cooling. In two-phase cooling, heat generated by the electrical components causes the coolant liquid to boil and evaporate to a gas, which is then condensed at the thermal interface with a heat exchanger so as to remove heat from the cooling module.

The power input may be a sealed conduit for a power connection into the volume of the cooling module, or may be a power plug, socket or other connector. The power input is arranged at the wall of the cooling module so as to allow entry of an electrical connection into the cooling module from an external power source. In some cases, the power input will be arranged at a rear plate or back plate of the cooling module, for instance on the same face as any data connections into the cooling module.

The power regulator may be any system configured to regulate the current and/or voltage such that the power is stabilised or controlled. In particular, electrical power (P) conforms to the relation P=IV (where I is the current, and V is the voltage). Power can also be seen as a measure of energy input (or work done) per unit time. The power regulator is configured to control the input power so as to regulate the electrical energy supplied to electrical components within the cooling module, and by this means to govern the excess energy (in the form of heat) available to be absorbed by the coolant fluid. In particular, to govern the amount of excess heat energy can be considered to limit, constrain or manage the amount of heat generated by the heat generating electrical component or the temperature change of the coolant.

Control or stabilisation of the power results in control or stabilisation of the heat generated by the electrical components housed within the cooling module. Excessive or rapid heating of the heat generating electrical components can be avoided because the power required to cause such an effect is prevented by use of the power regulator from reaching the heat generating electrical components or entering the immersion environment within the cooling module. Consequently, the excess energy input to the cooling module can be maintained at a level which can be removed by the cooling system under normal operation. Therefore, the coolant may be maintained at a temperature below the temperature at which chemical breakdown can occur.

A variety of coolant liquids may be used. Coolant liquids will be liquid at room temperature. Coolant liquids for single phase immersion cooling will be liquid under normal operating temperatures for the heat generating electrical component. However, those coolants used within the cooling module for two-phase immersion cooling should evaporate into a gas (i.e. have a boiling point) at normal operating temperatures of the heat generating electrical component, but be liquid at slightly lower temperatures. In either case, chemical breakdown of the coolant fluid should not occur at normal operating temperatures of the heat generating electrical component. Examples of suitable coolant liquids include natural oils, synthetic oils, fluoro-octanes (for instance Fluorinert™) hydrofluoroether, HFE (for instance Novec™), hydrofluorolefin, HFO (for instance Vertrel Sinara™), perfluoroketone, PFK (for instance by Novec™), or perfluoropolyether, PFPE (for instance Solvay Galden™). However, this list is not exhaustive, and other coolant liquids may be used within the present invention.

The power regulator may comprise at least one or a combination of the following elements: a voltage regulator, a current regulator, a DC-DC converter, a voltage limiter, a current limiter, or overcurrent protector. Any electrical system or circuit suitable for stabilising or regulating the power may be used. For example, the power regulator may be a voltage regulator using a “feed-forward” design or using a negative feedback loop. Where the power regulator comprises a voltage regulator, either a DC or AC voltage may be stabilised. In some examples, the regulator will be a semiconductor power regulator or an isolated DC-DC converter. In every case, the power regulator is used to control or manage the power and thereby the amount of energy input to the cooling module.

In some cases the power regulator may be a plurality of parallel power regulators, configured such that in combination they regulate the power supplied into the cooling module. In any case, the power regulator or plurality of power regulators are configured so that the excess energy absorbed by the coolant is maintained below the energy input threshold at which chemical breakdown of the coolant liquid can occur.

Optionally, the power regulator may be arranged at an outer surface of the cooling module. For example, the power regulator may be attached to the outer casing or wall of the cooling module. In one example, the power regulator may be attached to the rear plate of the cooling module on which the power connectors and data connectors are also arranged. Beneficially, arranging the power regulator external to the cooling module means that excessive power is prevented from entering the volume of the cooling module in which the coolant is contained. Therefore, it is less likely for sufficient energy to enter the cooling module to cause chemical breakdown of the coolant. In this way, the power source is “isolated” from the bath of coolant liquid.

Optionally, the power regulator is air cooled. The power regulator may generate heat whilst in operation and so air cooling of the power generator is useful to reduce its operating temperature. Air cooling may take place by convection currents of air surrounding the cooling system, or by use of a mechanical fan to drive air currents over the surface of the cooling module in order to remove heat from the vicinity of the power regulator.

Preferably, the power regulator is thermally connected to a thermally conductive outer surface of the cooling module, such that the outer surface acts as a heat sink to conduct heat away from the power regulator. Ideally, the power regulator will be maintained at a relatively low operation temperature during operation. However, even under normal operation, the power regulator will generate heat. Accordingly, connecting the power regulator to a heat sink dissipates heat and acts to cool the power regulator. Conduction of heat away from the power regulator may be used in conjunction with other types of cooling such as air cooling.

Optionally, the thermally conductive outer surface is thermally connected to the coolant liquid such that heat is exchanged with the coolant liquid to cool the thermally conductive outer surface. In other words, the thermally conductive outer surface may be a face of the cooling module, wherein an inner surface of the face is in contact with the coolant liquid and the outer surface of the face is connected to the power regulator. In this way, heat may be transferred from the power regulator through the thermally conductive outer face to the coolant liquid, which then transfers the heat away from the thermally conductive outer face toward the thermal interface and heat exchanger of the cooling system. This may provide an especially efficient mechanism for cooling the power regulator.

Preferably, the power regulator regulates the power supplied to the heat generating electrical component so that the maximum supplied power is substantially constant, the magnitude of the substantially constant maximum supplied power determined according to the power rating of the heat generating electrical component. In other words, the pre-determined level for the power output from the power regulator is set relative to the power required under normal operation by the electrical components in the cooling module. In this way, the heat generating electrical component is not supplied with large amounts of excess energy to be absorbed by the coolant as heat.

Preferably, the magnitude of the substantially constant supplied power matches the power rating of the heat generating electrical component. In other words, the power regulator is configured to supply the maximum power required by the heat generating electrical components under normal operating conditions. The manufacturer of the heat generating electrical components may publish a prescribed power usage under normal conditions, or the power usage can be otherwise established. Beneficially, this allows the correct power to be supplied to the heat generating electrical components in order to operate without damage or excessive heating.

Alternatively, the power regulator regulates the power supplied to the heat generating electrical component to be within ±30% of the power rating of the heat generating electrical component. Beneficially, allowing the power regulator to supply a power within a bound set relative to the normal power usage allows for small fluctuations in the current or voltage supply. However, it prevents large fluctuations in the power being passed to the heat generating electrical components, and therefore prevents excessive heating of the heat generating electrical component and cooling liquid. The boundaries for the supplied power may be within any reasonable bounds of the power rating, for example within ±75%, ±50%, ±25%, ±20%, ±15%, ±10%, ±5%, ±2% or ±1% of the power rating of the heat generating electrical components.

Advantageously, the power regulator limits the power supplied to the heat generating electrical component to less than a predetermined limit of 200% of the maximum power rating of the heat generating electrical component. Alternatively the predetermined limit could be another limit such as 175%, 150%, 120%, 105% or 102%. Beneficially, the power regulator limits the power to less than a predetermined limit, the limit determined according to the power rating of the electrical components. The selection of the configuration of the power regulator may be made in view of the maximum power required by the heat generating electrical components in normal use, weighed with the availability and economic viability of a specific type of power regulator. In an example in which the cooling module contains a plurality of heat generating components, the power supplied by the power regulator may be selected according to the power requirements of the heat generating component of the plurality of heat generating components that requires the maximum power.

The power regulator is configured to prevent the power input to the cooling module exceeding a certain level. Beyond this level, the power regulator may be arranged to create an open circuit to prevent further power input to the cooling module. This avoids the heat generating electrical components drawing enough power to heat the coolant liquid to temperatures high enough to cause chemical breakdown. The predetermined limit will be set by the power rating of the power regulator and selected at manufacture of the cooling system according to the power requirements of the electrical components housed within the cooling module. In a particular example, 60 kW of 48V DC power will be available to the cabinet or chassis into which the cooling system is connected (and from which power is obtained). However, the power regulator at the cooling system will be used to stabilise the power available to the electrical components within the cooling module to 400 W or 720 W. The specific power level is set according to the requirements of the particular electronic components mounted within the cooling module.

Preferably, all power received at the heat generating electrical component is passed through the power regulator. Therefore, no power is passed to the heat generating electrical components without regulation to the required level. Accordingly, under normal operation of the cooling system to remove head from the coolant, excessive power should not be available to the heat generating electrical components to the extent that it would allow heating of the coolant to a temperature which would cause chemical breakdown. In one example, the power regulator is placed at the power input (either immediately before or immediately after the power input) so that all power entering the cooling module is appropriately regulated. In this way, the power regulator acts as a controller of the energy entering the cooling module and available for generating heat at the heat generating electrical components to be transferred to the coolant liquid.

The power regulator may be integral to the power input. For instance, the power regulator and power input may be comprised within a single element or module. Alternatively, the power regulator and power input may be separate modules, elements or devices, each mounted within the electrical circuitry of the cooling module.

Preferably, the power regulator is connected directly adjacent the power input. In other words, in a particular example the power input is arranged immediately following the power regulator in a series circuit.

Preferably, the cooling module further comprises the heat generating electrical component being mounted on a circuit board within the volume of the sealable module. The circuit board may be substantially planar and housed or mounted within the volume defined within the cooling module. The circuit board may be a printed circuit board (PCB), for example, or other surface providing electrical connections. The circuit board may be immersed in the coolant fluid. In a particular example, the circuit board may be arranged within the cooling module opposite a thermally conductive interface with the heat exchanger. In this way, convection currents within the coolant fluid can transport heat away from the electrical components to the heat exchanger, to then be removed from the cooling module. This immersive cooling configuration may provide a large surface area for enabling effective cooling by allowing exchange of heat from the electrical components to the coolant fluid and onwards to the heat exchanger. Beneficially, this may allow for more efficient cooling of the electrical components.

The power regulator may be a first power regulator, and the cooling system may further comprise a second power regulator. In other words, more than one power regulator may be present within the cooling system. For example, an external power regulator may be used as a first power regulator, with a second power regulator being a DC-DC converter. In one instance, a first power regulator stabilises and limits the power entering the cooling module, and the second power regulator converts the power to a specific, required voltage.

The first power regulator may be arranged external to the cooling module, and the second power regulator may be arranged within the sealed volume of the cooling module. In one example, a first power regulator may be arranged at the power input and external to the cooling module, and a second power regulator may be arranged inside the volume defined by the cooling module so as to be immersed. The second power regulator may then be used to convert the voltage within the cooling module, whilst the first power regulator ensures that only a stable, predetermined power is able to enter the cooling module. In another example, the second power regulator may be arranged at a local input to one particular heat generating electrical component amongst a plurality of heat generating electrical components mounted within the cooling module. Immersion of the second power regulator within the cooling module improves the efficiency of cooling of the second power regulator.

Optionally, the heat generating electrical component is mounted on a circuit board within the sealed volume of the cooling module. The second power regulator may be arranged on the circuit board.

Preferably, the coolant liquid comprises dissolved oxygen. This is useful as a further safety measure in the event of excessive heating of the coolant fluid in the cooling module. At a predetermined temperature (higher than the normal operating temperature of the coolant liquid) the dissolved oxygen is released or liberated from the coolant fluid. The oxygen will especially be released when the coolant fluid boils. Upon release of the oxygen into the volume of the cooling module, heat generating components, in particular those experiencing excessive heating, will begin to oxidise. Similarly, connections or wires (for example at a circuit board) which connect the power input to the heat generating component may also begin to oxidise. Advantageously, as the surface of the heat generating component or a connection portions oxidise, the resistance will increase between the heat generating electrical component and the power input. This in turn reduces the power supplied to the heat generating component. Consequently, the amount of heat generated by the heat generating component will decrease. In some circumstances, oxidation of the heat generating component or its electrical connections may cause the electrical connection to the heat generating component to “burn-out”, fuse or breakdown completely. Therefore, the use of oxygen dissolved in the coolant liquid provides a further safety measure to reduce the likelihood of the coolant liquid in the cooling module reaching a temperature which would allow chemical breakdown.

In addition, the presence of oxygen in the immersion environment reduces the likelihood of generating potentially hazardous chemicals such as PFIB or HF in the event of breakdown of the coolant fluid. This is because presence of oxygen during the chemical breakdown will result in different, less dangerous chemical breakdown products.

Preferably, an element comprising aluminium or aluminium oxide is arranged within the volume of the cooling module. The element may be a sacrificial element. The element may be immersed in the coolant, and will have direct liquid contact with the coolant. Where the chemical breakdown products of the coolant fluid are reactive with aluminium or aluminium based materials, the presence of an element comprising aluminium or aluminium oxide within the volume of the cooling module can be used to neutralise any harmful chemical breakdown products. Examples of common chemical breakdown products of certain coolant fluids are PFIB and HF. The aluminium in the element can react with the PFIB and/or HF to give further chemical components which are less harmful to human health.

Optionally, the element comprising aluminium or aluminium oxide is a coating comprising aluminium or aluminium oxide, the coating arranged on at least a portion of an inner surface of the cooling module, the inner surface defining the volume. For example, at least part of the inside wall of the volume defined within the cooling module may be coated with aluminium or aluminium oxide. In one example, the inner surfaces are anodised aluminium. By using a coating of material comprising aluminium or aluminium oxide, a large surface area of aluminium or aluminium oxide is provided for reaction with any chemical breakdown products of the coolant fluid that are produced. Alternatively, the element can be a component or coating of a device within the cooling module. The element may also be a coating on the heat transfer surface or thermal interface of the cooling module. Beneficially, use of an element comprising aluminium or aluminium oxide provides a mechanism for transformation of hazardous chemical breakdown products into less harmful chemicals.

In some cases, the element may comprise at least one of the materials selected from a group comprising: an alkali metal oxide, an alkali metal hydroxide, an alkaline earth oxide, an alkaline earth hydroxide, silicon oxide, tin oxide, zinc oxide, alkaline earth basic carbonate, an alkaline earth basic phosphate, or transition metal oxide particles. The element may comprise these materials or a mixture of these materials instead of aluminium or aluminium oxide, or in a mixture with aluminium or aluminium oxide. Each of the listed metals may react with PFIB to result in a new chemical product that may be less hazardous to human health. The appropriate metal should be selected in view of the coolant fluid, the temperature in the cooling module under normal operating conditions, and the particular heat generating components in the cooling module.

Preferably, the volume is sealed. In other words, the coolant liquid may be sealed within the cooling module. Accordingly, the volume in which the coolant fluid can be contained is a fixed volume.

Beneficially, the cooling module further comprises a pressure release seal arranged to open the sealed volume of the cooling module when the pressure inside the sealed volume exceeds a threshold pressure. For example, in the event of excessive heating of a heat generating component the temperature of the coolant fluid is increased, thereby causing the pressure within the cooling module to increase. If left unchecked, the coolant fluid would first boil and eventually reach a temperature at which the coolant experiences chemical breakdown. In order to avoid excessive heating of the coolant liquid, a pressure release value can the opened at a threshold pressure. The threshold pressure can be selected to correspond to a predetermined threshold temperature for a given volume and type of coolant fluid (for example, according to the phase diagram for that coolant type). The predetermined threshold temperature may be less than, or substantially less than, the chemical breakdown temperature of the given coolant fluid. In this way, the pressure seal can be used to prevent chemical breakdown of the coolant fluid.

Alternatively, the cooling module may further comprise a temperature release seal arranged to open the sealed volume of the cooling module when the temperature inside the sealed volume exceeds a threshold temperature. For example, in the event of excessive heating of a heat generating component (for example, due to a fault), excessive heating of the coolant fluid can occur. At a threshold temperature, the seals of the volume of the cooling module may “burn out”, soften or melt, thereby releasing the pressure within the cooling module. By opening the seal, both the pressure within the cooling module and the volume occupied by the coolant fluid is changed, and this causes the temperature of the coolant fluid to reduce. As such, the temperature release seal can be used to prevent the coolant fluid heating to a temperature at which chemical breakdown could take place.

Preferably, the cooling module further comprising a thermal interface arranged to transfer out of the volume the heat generated by the heat generating electrical component, the heat from the heat generating electrical component being absorbed by the coolant liquid and transported to the thermal interface via a convective current. For example, heat may be transferred away from the vicinity of the heat generating components by absorption of the heat by the coolant fluid. The heated coolant fluid then circulates via convection currents, in order to transfer the heat away from the heat generating components. A thermal interface may be positioned within the cooling module such that the convection currents move the heated coolant fluid toward the thermal interface. Heat may then be transferred out of the volume through the thermal interface. A surface of the thermal interface may be an inner surface of the sealable module, such that the surface of the thermal interface is at least one of the surfaces defining the volume.

Beneficially, the cooling system further comprising a heat exchanger, arranged to receive heat from the thermal interface and to transport the heat away from the cooling module. For instance, the heat exchanger may be arranged such that the thermal interface of the cooling module is positioned between the heat exchanger and the coolant fluid. Therefore, the heat transferred through the thermal interface from the coolant fluid may be received by the heat exchanger and transported away from the coolant module.

In a further aspect there is a method of preventing or halting overheating of a heat generating electrical component, comprising transferring heat generated by an electrical component to a coolant liquid comprising dissolved oxygen wherein the dissolved oxygen is liberated when the coolant liquid is above a predetermined temperature, wherein the electrical component is immersed in the coolant liquid; and, upon liberation of the dissolved oxygen, oxidising the electrical component causing the electrical component to reduce the heat generated. Beneficially, the oxidation causes increased resistance of a power input of the electrical component to reduce a current to the electrical component and thereby reduce the heat generated. In other words, when the coolant reached a predetermined temperature, the dissolved oxygen is released. The dissolved oxygen in the immersion environment may then oxidises at least a portion of the heat generating component and its input. Heat generating component operating at a higher temperature may be more susceptible to oxidation than those operating at a lower temperature. Oxidation may cause an increased electrical resistance to the heat generating component due to the reduced cross-sectional area through which conduction to the heat generating component can take place. This causes a reduction in current at the heat generating component. Accordingly, the operating temperature of the heat generating component may subsequently be reduced. In some circumstances, oxidation will cause the resistance at the input of the heat generating component to increase significantly. In some instances, the resistance will increase until the input to the heat generating electrical component is “burnt out” or fused, thereby breaking the electrical connection to the heat generating component completely. As a consequence, overheating of the heat generating component may be halted.

The dissolved oxygen could be in the form of dissolved air. Therefore, coolant which has not be degassed could be used, although coolant liquid in which oxygen is specifically dissolved may be preferable. In particular, the dissolved oxygen could be dissolved in the coolant in the form of “pure” oxygen. Alternatively, the dissolved oxygen could be provided as a component of a dissolved gas, the dissolved gas having more than 21% oxygen by volume (in other words, a dissolved gas comprising an oxygen content more than that of air). For example, the oxygen content of the dissolved gas may be 25% or more, 50% or more, or 75% or more, by volume. Pure oxygen may have an oxygen content of more than 99%.

As a consequence of using coolant fluid comprising dissolved oxygen, the production of harmful products as a result of chemical breakdown of the coolant fluid may be reduced. In the presence of oxygen, coolant fluids such as perflurocarbons are less likely to breakdown to produce PFIB. Therefore the presence of oxygen in the cooling module in the event of chemical breakdown of the coolant fluid is less likely to result in hazardous or harmful chemicals such as PFIB or HF.

Preferably, the circulation of coolant liquid within the cooling module takes place only through convection currents. In other words, the cooling system is not pumped to circulate the coolant fluid and to transfer the heat away from the vicinity of the heat generating components. Circulation of the coolant fluid occurs only through convection, without being mechanically forced. In particular, pumping an oxygenated gas can result in failure of the circulation system.

Ideally, the cooling system using a coolant comprising dissolved oxygen will be a single-phase cooling system. In other words, the coolant will remain in the liquid phase throughout circulation. Ideally, boiling of the coolant comprising dissolved oxygen should be avoided during normal operation, as this will cause the oxygen to be released or liberated.

Preferably, the coolant liquid is fluorinated or partially fluorinated fluid, in particular the coolant liquid may be a perflurocarbon. In particular example, the coolant fluid is Perfluoropolyether. Examples of suitable coolant liquids include natural oils, synthetic oils, fluoro-octanes (for instance Fluorinert™), hydrofluoroether, HFE (for instance Novec™) hydrofluorolefin, HFO (for instance Vertrel Sinara™), perfluoroketone, PFK (for instance by Novec™), or perfluoropolyether, PFPE (for instance Solvay Galden™). However, this list is not exhaustive, and other coolant liquids may be used within the present invention.

Preferably, the heat generating electrical component comprises a computer component. For example, the heat generating electrical component may form part of a CPU or be used for data storage. There may be more than one heat generating electrical component mounted within the cooling module.

In a further aspect there is a cooling system, comprising a cooling module defining a volume; a coolant liquid comprising dissolved oxygen, wherein the dissolved oxygen is liberated when the coolant liquid is heated above a predetermined temperature, the coolant liquid being contained within the volume; and a heat generating electrical component mounted in the volume so as to be immersed in the coolant liquid, the heat generated by the heat generating electrical component absorbed by the coolant liquid, wherein the heat generating electrical component is configured to reduce its heat generation when oxidised by exposure to oxygen liberated from the coolant liquid. Beneficially, the oxidation causes increased resistance of a power input of the heat generating electrical component, resulting in a reduced input current causing less heat to be generated.

Upon release of the oxygen into the volume of the cooling module, heat generating components, in particular those experiencing excessive heating, will begin to oxidise. Similarly, connections or wires (for example at a circuit board) which connect the power input to the heat generating component may also begin to oxidise. The oxidation increases the electrical resistance of the heat generating component and reduces the current drawn by the component. In some cases, oxidation may increase the resistance significantly. Alternatively, oxidation of the heat generating component or its electrical connections may cause the electrical connection to the heat generating component to “burn-out”, fuse or breakdown completely. For example, the surface of a wire or input at the heat generating component may oxidise, reducing the cross-sectional area of the wire able to conduct a current. This results in a significant increase in the resistance through the oxidised portion of the wire. Eventually, the local resistance of the input wire will increase to the extent that it will melt or break. As a consequence the circuit to the device is broken, and the circuit is fused. As a result, the heat generating component will no longer produce heat.

Advantageously, the presence of dissolved oxygen improves the safety of the cooling system by disabling a faulty heat generating component. As a result, the excess energy able to be dissipated from the heat generating component to the coolant fluid is reduced, thereby reducing the likelihood of excessive heating of the coolant fluid to the chemical breakdown temperature. In particular, use of dissolved oxygen in the coolant fluid prevents runaway heating of the coolant fluid.

In addition, the presence of oxygen in the immersion environment reduces the likelihood of generating potentially hazardous chemicals such as PFIB or HF in the event of breakdown of the coolant fluid. Upon chemical breakdown of the coolant fluid, the oxygen will react to result in different, less dangerous chemical breakdown products. For example, the production of PFIB may be eliminated, as coolant breakdown can result in the production of COF₂, rather than CF₂.

Preferably, the volume is sealed. For example, the cooling module is a sealed container or volume. Beneficially, sealing the volume causes dissolved oxygen released from the coolant fluid to be captured in the volume, and so retained within the immersion environment. Therefore, the oxygen may be available for oxidisation of the heat generating contact.

Preferably, the cooling module further comprises a thermal interface arranged to transfer out of the volume the heat generated by the heat generating electrical component, the heat generated by the heat generating electrical component absorbed by the coolant liquid and transported to the thermal interface via a convection current. For example, heat may be transferred away from the vicinity of the heat generating components by absorption of the heat by the coolant fluid. The heated coolant fluid then circulates via convection currents, in order to transfer the heat away from the heat generating components. A thermal interface may be positioned within the cooling module such that the convection currents move the heated coolant fluid toward the thermal interface. Heat may then be transferred out of the volume through the thermal interface. A surface of the thermal interface may be an inner surface of the sealable module, such that the surface of the thermal interface is at least one of the surfaces defining the volume.

Preferably, the circulation of coolant liquid to transport heat from the heat generating electrical component to the thermal interface takes place only via convection currents. In other words, the cooling system is not pumped to circulate the coolant fluid and to transfer the heat away from the vicinity of the heat generating components. Circulation of the coolant fluid occurs only through convection, without being mechanically forced. In particular, pumping an oxygenated gas can result in failure of the circulation system. Ideally, the coolant fluid remains in the liquid phase throughout the normal operation of the cooling system.

Preferably, the cooling system further comprises a heat exchanger, arranged to receive heat from the thermal interface and transport the heat away from the cooling module. For instance, the heat exchanger may be arranged such that the thermal interface of the cooling module is positioned between the heat exchanger and the coolant fluid. Therefore, the heat transferred through the thermal interface from the coolant fluid may be received by the heat exchanger and transported away from the coolant module.

Optionally, an element comprising aluminium or aluminium oxide is arranged within the volume of the cooling module. Where the chemical breakdown products of the coolant fluid are reactive with aluminium or aluminium based materials, the presence of an element comprising aluminium or aluminium oxide within the volume of the cooling module can be used to neutralise any harmful chemical breakdown products. For example, common chemical breakdown products of certain coolant fluids are PFIB and HF. The aluminium in the element can react with the PFIB and/or HF to result in further chemical components which are less harmful to human health.

Beneficially, the element comprising aluminium or aluminium oxide is a coating comprising aluminium or aluminium oxide, the coating on at least a portion of an inner surface of the cooling module, the inner surface defining the volume. For example, at least part of the inside wall of the volume defined within the cooling module may be coated with aluminium or aluminium oxide. By doing so, a large surface area of aluminium or aluminium oxide is provided for use to react with chemical breakdown products of the coolant fluid. The element may also be a coating on the heat transfer surface or thermal interface of the cooling module. Alternatively, a separate, sacrificial component may be included in the volume of the cooling module. The element has direct, liquid contact with coolant.

The cooling module may further comprise a pressure release seal arranged to open the sealed volume of the cooling module when the pressure inside the sealed volume exceeds a threshold pressure. For example, in the event of excessive heating of a heat generating component the temperature of the coolant fluid is increased, thereby causing the pressure within the cooling module to increase. If left unchecked, the coolant fluid would first boil and eventually reach a temperature at which the coolant experiences chemical breakdown. In order to avoid excessive heating of the coolant liquid, a pressure release value can be opened at a threshold pressure. The threshold pressure can be selected to correspond to a predetermined threshold temperature for a given volume and type of coolant fluid (for example, according to the phase diagram for that coolant type). The predetermined threshold temperature may be less than, or substantially less than, the chemical breakdown temperature of the given coolant fluid. In this way, the pressure seal can be used to prevent chemical breakdown of the coolant fluid.

Optionally, the cooling module may further comprise a temperature release seal arranged to open the sealed volume of the cooling module when the temperature inside the sealed volume exceeds a threshold temperature. For example, in the event of excessive heating of a heat generating component (for example, due to a fault), increased heating of the coolant fluid can occur. At a threshold temperature, the seals of the volume of the cooling module may open, soften or “burn out”, thereby releasing the pressure within the cooling module. By opening the seal, both the pressure within the cooling module and the volume occupied by the coolant fluid is changed, and this causes the temperature of the coolant fluid to reduce. As such, the temperature release seal can be used to prevent the coolant fluid heating to a temperature at which chemical breakdown could take place.

In a further aspect there is a cooling system for cooling a heat generating electrical component, comprising a cooling module defining a volume; a coolant liquid being contained within the sealed volume, the coolant liquid to absorb excess energy from the heat generating electrical component, wherein the coolant liquid has an energy input threshold above which chemical breakdown of the coolant liquid occurs, and wherein at least one chemical breakdown product of the coolant liquid reacts with aluminium or aluminium oxide; and at least one element arranged within the volume, the at least one element comprising aluminium and/or aluminium oxide.

Advantageously, the chemical breakdown products of some common coolant fluids a reactive with aluminium or aluminium containing compounds. For example, where the coolant liquid is a hydroflurocarbon or a perflurocarbon, the coolant may breakdown at a chemical breakdown temperature into products including PFIB and/or HF. These chemical breakdown products are hazardous to human health, even in small quantities. However, in the presence of aluminium containing materials, the chemical by-products (in particular PFIB) my react further with the aluminium to result in less harmful chemical products. Accordingly, inclusion of one or more aluminium or aluminium oxide elements within the cooling module may be used as a sacrificial element to react with any amounts of PFIB or other harmful chemical breakdown products produced. In this way, safety of the system is improved. In further examples, the aluminium containing materials may be used to neutralise acidity caused by chemical breakdown of the coolant liquid, for example, by reaction with HF.

Optionally, the at least one element comprises a coating on at least a portion of an inner surface of the cooling module, the inner surface defining the volume. Coating at least a portion of the inner surfaces of the cooling module (wherein the inner surfaces define the volume containing the coolant) provides a large surface area for reaction with any PFIB or hazardous chemical breakdown product produced. In a particular example, the inner surfaces of the cooling module are anodised to provide aluminium oxide at the surface. The element may also be a coating on the heat transfer surface or thermal interface of the cooling module.

Optionally, the at least one element comprises an element mounted within the volume. For instance, the element might be a component or part of a component, such as a surface or coating of a component. The component may be a sacrificial component, intended to provide a reactant to react with a product of the chemical breakdown products of the coolant liquid.

In some cases, the element may comprise at least one of the materials selected form a group comprising: an alkali metal oxide, an alkali metal hydroxide, an alkaline earth oxide, an alkaline earth hydroxide, silicon oxide, tin oxide, zinc oxide, alkaline earth basic carbonate, an alkaline earth basic phosphate, or transition metal oxide particles. The element may comprise these materials or a mixture of these materials instead of aluminium or aluminium oxide, or in a mixture with aluminium or aluminium oxide. Each of the listed metals may react with PFIB to result in a new chemical product that may be less hazardous to human health. The appropriate metal should be selected in view of the coolant fluid, the temperature in the cooling module under normal operating conditions, and the particular heat generating components in the cooling module.

Beneficially, the coolant liquid further comprises dissolved oxygen. This is useful to provide a further safety measure in the event of excessive heating of the coolant fluid in the cooling module. At a predetermined temperature (higher than the normal operating temperature of the coolant liquid) the dissolved oxygen is released or liberated from the coolant fluid. Upon release of the oxygen into the volume of the cooling module, heat generating components may begin to oxidise. Similarly, connections or wires (for example at a circuit board) which connect the power input to the heat generating component may also begin to oxidise. Advantageously, as the surface of the heat generating component or a connection portion oxidises, the resistance between the heat generating electrical component and the power input will increase. This in turn reduces the power supplied to the heat generating component. Consequently, the amount of heat generated by the heat generating component will be decreased. In some circumstances, oxidation of the heat generating component or its electrical connections may cause the electrical connection to the heat generating component to “burn-out”, fuse or breakdown completely. In addition, the presence of oxygen in the immersion environment reduces the likelihood of generating potentially hazardous chemicals such as PFIB or HF in the event of breakdown of the coolant fluid, as the oxygen will react to result in different, less dangerous chemical breakdown products.

Preferably, the cooling module further comprises a thermal interface arranged to transfer out of the volume heat generated by the heat generating electrical component, the heat generated by the heat generating electrical component being absorbed by the coolant liquid and transported to the thermal interface via a convection current. For example, heat may be transferred away from the vicinity of the heat generating components by absorption of the heat by the coolant fluid. The heated coolant fluid then circulates via convection currents, in order to transfer the heat away from the heat generating components. A thermal interface may be positioned within the cooling module such that the convection currents move the heated coolant fluid toward the thermal interface. Heat may then be transferred out of the volume through the thermal interface. The thermal interface may be a wall for the cooling module.

Preferably, the cooling system further comprises a heat exchanger, arranged to receive heat from the thermal interface and to transport the heat away from the cooling module. For instance, the heat exchanger may be arranged such that the thermal interface of the cooling module is positioned between the heat exchanger and the coolant fluid. Therefore, the heat transferred through the thermal interface from the coolant fluid may be received by the heat exchanger and transported away from the coolant module.

Optionally, the cooling module further comprising a pressure release seal arranged to open the sealed volume of the cooling module when the pressure inside the sealed volume exceeds a threshold pressure. For example, in the event of excessive heating of a heat generating component the temperature of the coolant fluid is increased, thereby causing the pressure within the cooling module to increase. If left unchecked, the coolant fluid would first boil and eventually reach a temperature at which the coolant experiences chemical breakdown. In order to avoid excessive heating of the coolant liquid, a pressure release value can be opened at a threshold pressure. The threshold pressure can be selected to correspond to a predetermined threshold temperature for a given volume and type of coolant fluid (for example, according to the phase diagram for that coolant type and system volume). The predetermined threshold temperature may be less than, or substantially less than, the chemical breakdown temperature of the given coolant fluid. In this way, the pressure seal can be used to prevent chemical breakdown of the coolant fluid.

Optionally, the cooling module may further comprise a temperature release seal arranged to open the sealed volume of the cooling module when the temperature inside the sealed volume exceeds a threshold temperature. For example, in the event of excessive heating of a heat generating component (for example, due to a fault), excessive heating of the coolant fluid can occur. At a threshold temperature, the seals of the volume of the cooling module may “burn out”, melt or soften, thereby releasing the pressure within the cooling module. By opening the seal, both the pressure within the cooling module and the volume occupied by the coolant fluid is changed, and this causes the temperature of the coolant fluid to be reduce. As such, the temperature release seal can be used to prevent the coolant fluid heating to a temperature at which chemical breakdown could take place.

In a further aspect there is a method for cooling a heat generating electrical component in a cooling system, comprising providing a cooling module defining a volume; providing a coolant liquid contained within the sealed volume, the coolant liquid able to absorb excess energy from the heat generating electrical component, wherein the coolant liquid has an energy input threshold above which chemical breakdown of the coolant liquid occurs, and wherein at least one chemical breakdown product of the coolant liquid reacts with aluminium or aluminium oxide; and arranging at least one element within the volume, the at least one element comprising aluminium and/or aluminium oxide.

In a further aspect there is a cooling system for cooling a heat generating electrical component, comprising a coolant liquid to absorb excess energy by immersion of the heat generating electrical component wherein the coolant liquid has a temperature threshold above which chemical breakdown of the coolant liquid occurs; a cooling module defining a sealed volume, the coolant liquid being contained within the sealed volume and the heat generating electrical component being immersed in the coolant liquid, the sealed volume having at least one seal which opens at a predetermined pressure or predetermined temperature corresponding to a temperature of the coolant liquid at a predetermined value below the temperature threshold. In some examples, a plurality of seals may be used, some of which may be pressure seals, and some temperature seals.

The coolant fluid absorbs energy from the heat generating component in the form of heat. At a particular energy threshold, the coolant fluid will breakdown into different chemical products. The precise temperature of the chemical breakdown may be dependent on the pressure and volume within the cooling module, as both the pressure and temperature act to store energy within the coolant fluid. Accordingly, for a given volume of a specific coolant, a particular temperature and pressure threshold may be set for opening of the temperature or pressure seal. The threshold temperature or pressure corresponds to the coolant liquid having an energy below the energy required for chemical breakdown.

The at least one seal may be any seal which fails at a threshold temperature or pressure. For example, the seal may be a pressure seal which opens at a specific pressure, or a one way value which allows a fluid to pass when a particular pressure is present on a input side of the valve. In an alternative, the seal may comprise a material (such as a wax or a metal alloy) which melts at a specific temperature. At the point which the seal melts, a conduit from the pressurised portion of the system to the outside is opened. The at least one seal will be arranged in the wall of the cooling module, between the volume and atmosphere.

Advantageously, as a result of the change in pressure within the cooling module due to the opening of the seal, the temperature within the cooling module will reduce. Furthermore, the coolant may be released from the cooling module before chemical breakdown of the coolant liquid can occur. For instance, at a first temperature the coolant fluid may boil, and at a much higher temperature chemical breakdown can occur. The seal should open at a temperature lower than the chemical breakdown temperature, and optionally lower than the boiling point.

Optionally, the coolant liquid further comprises dissolved oxygen. This is useful as a further safety measure in the event of excessive heating of the coolant fluid in the cooling module. At a predetermined temperature (higher than the normal operating temperature of the coolant liquid) the dissolved oxygen is released or liberated from the coolant fluid. Upon release of the oxygen into the volume of the cooling module, heat generating components, in particular those experiencing excessive heating, will begin to oxidise. Similarly, connections or wires (for example at a circuit board) which connect the power input to the heat generating component may also begin to oxidise. Advantageously, as the surface of the heat generating component or a connection portion oxidises, the resistance between the heat generating electrical component and the power input will increase. This in turn reduces the power supplied to the heat generating component. Consequently, the amount of heat generated by the heat generating component will be decreased. In some circumstances, oxidation of the heat generating component or its electrical connections may cause the electrical connection to the heat generating component to “burn-out”, fuse or breakdown completely. Therefore beneficially the use of oxygen dissolved in the coolant liquid provides a further safety measure to reduce the likelihood of the coolant liquid in the cooling module heating to a temperature which would allow chemical breakdown. In addition, the presence of oxygen in the immersion environment reduces the likelihood of generating potentially hazardous chemicals such as PFIB or HF in the event of breakdown of the coolant fluid, as the oxygen will react to result in different, less dangerous chemical breakdown products.

Optionally, an element comprising aluminium or aluminium oxide is arranged within the volume of the cooling module. Where the chemical breakdown products of the coolant fluid are reactive with aluminium or aluminium based materials, the presence of an element comprising aluminium or aluminium oxide within the volume of the cooling module can be used to neutralise any harmful chemical breakdown products. For example, common chemical breakdown products of certain coolant fluids are PFIB and HF, which may react with aluminium to result in further chemical components which are less harmful to human health.

Optionally, the element comprising aluminium or aluminium oxide is a coating comprising aluminium or aluminium oxide on at least a portion of an inner surface of the cooling module, the inner surface defining the volume. For example, at least part of the inside wall of the volume defined within the cooling module may be coated with aluminium or aluminium oxide or may be an anodised aluminium layer. The element may also be a coating on the heat transfer surface or thermal interface of the cooling module. Alternatively, a sacrificial element comprising aluminium may be included in the cooling module.

Preferably, the cooling module further comprises a thermal interface arranged to transfer out of the volume heat generated by the heat generating electrical component, the heat generated by the heat generating electrical component being absorbed by the coolant liquid and transported to the thermal interface via a convection current. For example, heat may be transferred away from the vicinity of the heat generating components by absorption of the heat by the coolant fluid. The heated coolant fluid then circulates via convection currents, in order to transfer the heat away from the heat generating components. A thermal interface may be positioned within the cooling module such that the convection currents move the heated coolant fluid toward the thermal interface. Heat may then be transferred out of the volume through the thermal interface.

Preferably, the cooling system further comprising a heat exchanger, arranged to receive heat from the thermal interface and to transport the heat away from the cooling module. For instance, the heat exchanger may be arranged such that the thermal interface of the cooling module is positioned between the heat exchanger and the coolant fluid. Therefore, the heat transferred trough the thermal interface from the coolant fluid may be received by the heat exchanger and transported away from the coolant module.

Preferably, the coolant liquid is a fluorinated or partially fluorinated fluid, and in particular a perflurocarbon. In one specific example, the coolant liquid is perfluoropolyether. These types of coolant are particularly advantageous for use with all embodiments of the invention discussed herein. Coolant liquids will be liquid at room temperature. Coolant liquids for single phase immersion cooling will be liquid under normal operating temperatures for the heat generating electrical component. However, those coolants used within the cooling module for two-phase immersion cooling should evaporate into a gas at normal operating temperatures of the heat generating electrical component, but be liquid at slightly lower temperatures (in other words, the boiling point of the coolant fluid for two-phase cooling should be around or just below the normal operating temperature of the heat generating components). In either case, chemical breakdown of the coolant fluid should not occur at normal operating temperatures of the heat generating electrical component. Examples of suitable coolant liquids include natural oils, synthetic oils, fluoro-octanes (for instance Fluorinert™), hydrofluoroether, HFE (for instance Novec™), hydrofluorolefin, HFO (for instance Vertrel Sinara™), perfluoroketone, PFK (for instance by Novec™), or perfluoropolyether, PFPE (for instance Solvay Galden™) However, this list is not exhaustive, and other coolant liquids may be used within the present invention.

Preferably, the heat generating electrical component comprises a computer component in each of the embodiments discussed herein. In particular, the invention may be particularly useful for cooling computer components such as CPUs, hard drives or memory modules, for instance mounted on a circuit board or motherboard within the cooling module.

In a further aspect there is a method for cooling a heat generating electrical component in a cooling system, comprising providing a coolant liquid to absorb excess energy by immersion of the heat generating electrical component wherein the coolant liquid has a temperature threshold above which chemical breakdown of the coolant liquid occurs; providing a cooling module defining a sealed volume, the coolant liquid being contained within the sealed volume and the heat generating electrical component being immersed in the coolant liquid, the sealed volume having at least one seal which opens at a predetermined pressure or predetermined temperature corresponding to a temperature of the coolant liquid at a predetermined value below the temperature threshold. In some examples, a plurality of seals may be used, some of which may be pressure seals, and some temperature seals.

It will be understood that method features corresponding with the structural, system features described herein may optionally be provided in conjunction with the above-described system. The combination of any of the system or method features described herein, or the combination of both system and method features, is also provided even if not explicitly disclosed.

### BRIEF DESCRIPTION OF THE DRAWINGS

A cooling system in accordance with an aspect of the present disclosure is described, by way of example only, with reference to the following drawings, in which:

FIG. 1 is a projection view of the cooling module arranged to be inserted into a corresponding cabinet;

FIG. 2 is a cross-sectional view from a first side of a first example of the cooling system;

FIG. 3 is a plan view of a second side of the first example of the cooling system;

FIG. 4 is a cross-sectional view from a first side of a second example of the cooling system;

FIG. 5 is a cross-sectional view from a first side of a third example of the cooling system;

FIG. 6 is a cross-sectional view from a first side of a fourth example of the cooling system; and

FIG. 7 is a plan view of a second side of the fourth example of the cooling system.

Where appropriate, like reference numerals denote like elements in the figures. The figures are not to scale.

### DETAILED DESCRIPTION OF SPECIFIC EMBODIMENTS OF THE INVENTION

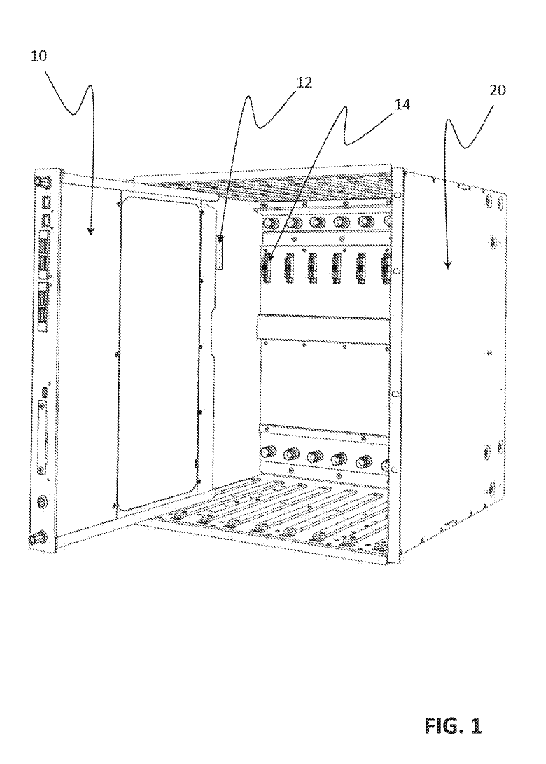

Referring first to FIG. 1, there is shown a cabinet or chassis 20. This type of cabinet may be used, for instance, within a networked computing environment in order to house a number of data servers.

The cabinet or chassis 20 is arranged to receive one or more cooling system 10 (also known as cooling blades, or cooling fins). Each cooling system 10 houses one or more heat generating electrical components for operation within a network. For example, each cooling system 10 may house motherboards, central processing units (CPUs) and memory modules to form a data server. Said electrical components can dissipate large amounts of heat, even during normal operation, and so the cooling system is configured to efficiently and effectively remove heat from the vicinity of the electrical components.

The cabinet 20 is configured having power connectors 14, which are arranged to correspond to a reciprocal power connector 12 arranged at a rear surface of each cooling system 10. The power connectors 12, 14 are arranged to receive an electrical input from the chassis or cabinet 20 to the cooling system 10. The cabinet 20 is connected to an external power source such as mains power or an electrical generator, for example. In most cases, the level of the power (in particular, the voltage) received at the cabinet 20 will be substantially higher than required for normal operation of the electrical components housed within the cooling system 10.

Further connectors may be present at the cooling system 10 (although not shown in FIG. 1). For example, a connector for input and output of coolant fluid may be present, to connect with a reciprocal connector at the cabinet 20. This may allow circulation of coolant between the cabinet 20 and a heat exchanger in the cooling system 10, for instance. Further connectors present at the cooling system 10 may include data or network connections, plugs or sockets.

In use, the cooling system 10 is inserted or slotted into the cabinet 20. The cooling system 10 is inserted into the cabinet 20 until the reciprocal power connectors 12, 14 are connected, in order to maintain a power connection. In this example, the power connectors 12, 14 supply a DC voltage from the cabinet 20 to the cooling system 10. Once the cooling system 10 is fully inserted into the cabinet 20, any other types of connectors, plugs or sockets configured between the cabinet 20 and cooling system 10 will also be connected.

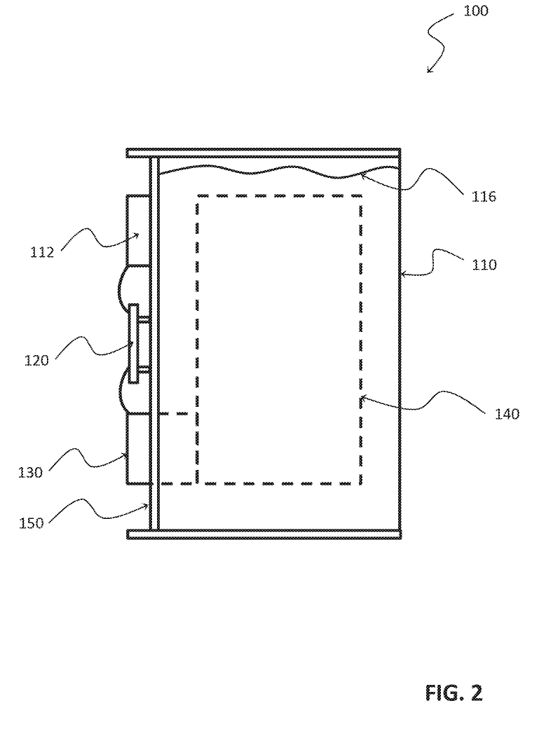

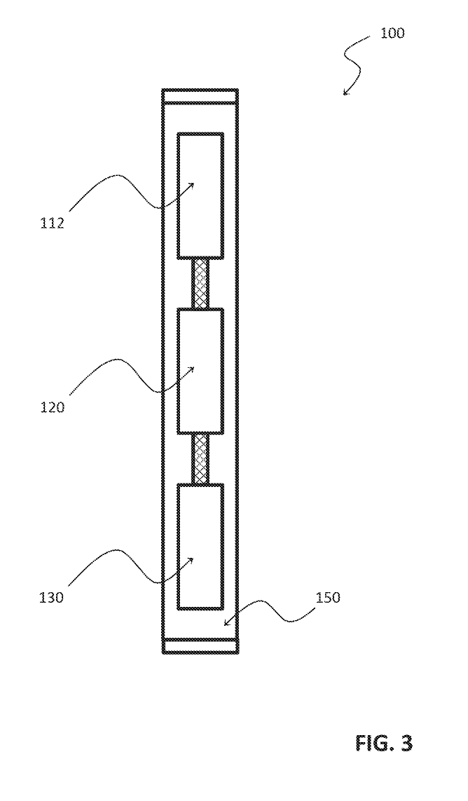

FIG. 2 shows a cross-sectional view of an example configuration for the cooling system 100, with FIG. 3 showing a view of the rear plate of the same cooling system 100. The cooling system 100 can be slotted or inserted into a cabinet or chassis as illustrated in FIG. 1.

The cooling system 100 comprises a sealable unit or cooling module 110 defining a volume in which at least one heat generating electrical component is housed (for example, mounted on a circuit board 140). At least one internal surface of the cooling module 110 will be arranged as a thermal interface, through which heat can be transferred to a heat exchanger to transfer heat out of the cooling module 110. A variety of sealed connections to the inside of the cooling module 110 may be included for input or output of coolant fluid and/or data or network connections to the components mounted at the circuit board 140. Said electrical components and connections are not shown in FIG. 2.

Coolant fluid 116 is contained within the volume defined by the cooling module 110. The level of the coolant fluid 116 is sufficient to immerse the heat generating electrical components, thereby creating a large surface area for transfer of heat from the electrical components to the coolant fluid. As a result, the temperature of the coolant fluid 116 closest to the heat generating electrical component is increased. Cooling of the heat generating electrical components may proceed via convection in the cooling fluid, which may subsequently conduct heat from the cooling fluid to a thermal interface with a heat exchanger. The precise cooling mechanism used by the cooling system is beyond the scope of this patent application, but examples of suitable cooling system are described in International Patent Application PCT/GB2014/050616, International Patent Application PCT/GB2010/000950, International Patent Application PCT/GB2014/050615 or U.S. Pat. No. 7,609,518. This invention is not exclusively for use with the systems described therein, however.

In this example, a coolant liquid 116 is used in which oxygen is dissolved. This has benefits in the event that any chemical breakdown of the coolant liquid occurs, as described further below. However, the configuration shown in FIGS. 2 and 3 could be used with other types of coolant which do not contain dissolved oxygen.

The cooling system 100 further comprises a power connector 112, a power regulator 120 and a power input 130. The power connector 112 is arranged to allow connection to a reciprocal connector within the cabinet or chassis 20. The power connector 112 receives a DC voltage from a power supply connected to the cabinet 20.

The power connector 112 is in connection with the power regulator 120. The power regulator 120 is subsequently connected to the power input 130. The power input 130 in this example comprises a connection to a plurality of heat generating electrical components within the cooling system 110 and mounted on the circuit board 140. Accordingly the power input 130 supplies power to the circuit board 140.

In the present example, the power regulator 120 comprises a voltage regulator and a fully isolated DC-DC converter connected in series. The voltage regulator stabilises the voltage applied to the power input and the DC-DC converter acts to convert or “step-down” the voltage to a pre-determined level. For example, the cabinet or chassis 20 may receive a power of 60 kW of 48V DC voltage. The power regulator 120 regulates the power such that the voltage passed to the circuit board 140 cannot exceed 720 W. The precise limit for the voltage is set according to the requirements of the electrical components situated at the circuit board 140. The magnitude of the regulated voltage will be pre-determined at the time of manufacture of the cooling system 100. In another particular example of the system shown in FIGS. 2 and 3, the power regulator is configured to pass to the circuit board 140 a voltage not exceeding 400 W.

In use, a DC voltage is received at the cooling system 100 through the power connector 112. The DC voltage is passed to the power regulator 120 which stabilises the power by regulation of the voltage. The regulated voltage is then passed to the power input 130 to be directed to the circuit board 140 for powering the mounted electrical components. The power regulator prevents excessive power being supplied into the cooling module for use to heat the coolant liquid 116 above tis chemical breakdown temperature.

The power regulator 120 in FIGS. 2 and 3 is connected to the thermally conductive rear plate 150 of the cooling module. The rear palter 150 acts as a heat sink, dissipating heat from the power regulator during operation. In this example, the thermally conductive rear plate 150 is arranged having the power regulator 120 connected to a first side and the coolant liquid 116 in contact with an opposing second side. As a result, heat can be transferred through the thermally conductive rear plate 150 to the coolant liquid 116, in order to transfer heat away from the power regulator 120. In this way, the power regulator 120 is conductively cooled via the liquid cooling within the cooling module 110. The power regulator 120 is further air cooled by movement of air across the rear plate of the cooling module. In one example, the air flow is generated simply by convection currents, but in a further example the flow of air is driven by one or more mechanical fans. As such, the operating temperature of the power regulator 120 may be reduced.

Beneficially, in this configuration the power regulator 120 prevents the power input 130 to the cooling module 110 exceeding a predetermined threshold. In this way, the power at the chassis 20 is isolated from the immersion environment. The power regulator 120 acts as a barrier to excess energy ever entering the cooling module 110, and so limits the ability of the heat generating electrical components to heat the coolant fluid 116 and thereby cause chemical breakdown.

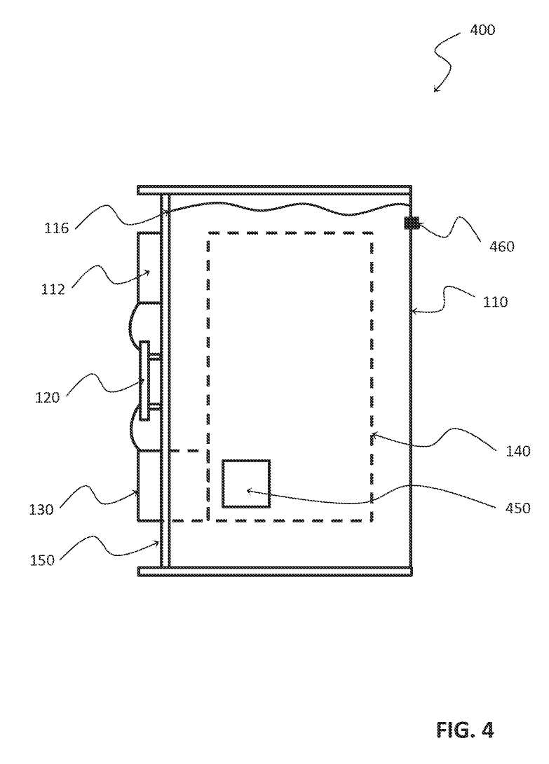

Turning to FIG. 4, a further example of the cooling system is illustrated. FIG. 4 shows a cross-sectional view of a further configuration for a cooling system 400. The cooling system 400 may be slotted or inserted into a cabinet or chassis as illustrated in FIG. 1, and have a rear plate as shown in FIG. 3.

As discussed above in relation to FIGS. 2 and 3, cooling system 400 comprises a cooling module 110 defining a sealable volume housing a circuit board 140 upon which a plurality of heat generating electrical components are mounted. The volume of the cooling module 110 contains a coolant fluid 116, which is used in combination with a heat exchanger arranged with respect to a thermal interface of the cooling module 110 to convectively cool the electrical components at the circuit board 140.

The cooling system 400 includes a power connector 112 arranged at an outer surface of the cooling module 110, for connection with a reciprocal power connector at the cabinet or chassis 20. The cooling system 400 further comprises a power regulator 120 connected to a power input 130. The power input 130 is arranged in connection with the circuit board 140 within the cooling module 110, in order to provide power to the electrical components on the circuit board 140. As discussed in relation to FIGS. 2 and 3, the power regulator is used to regulate the power input to the cooling module 110.

In the configuration illustrated in FIG. 4, the circuit board 140 is immersed in the coolant fluid 116 together with each electrical component mounted at the circuit board 140. As such, the electrical components will be cooled via convection and conduction. Beneficially, using immersion cooling of the electrical components may be an efficient and effective method of cooling.

The cooling system of FIG. 4 also comprises an element 450 mounted at the circuit board. The element 450 has an aluminium oxide outer coating. In addition, a pressure seal 460 is arranged in the wall of the cooling module 110. The pressure seal 460 is arranged to open when the pressure within the cooling module 110 reaches a threshold pressure. The pressure threshold is selected for a particular coolant and a particular volume of coolant liquid. The pressure threshold pressure corresponds to a predetermined temperature and pressure, where the predetermined temperature is below the temperature required to cause chemical breakdown of the selected coolant in the system.

In the event of a fault at one or more electrical component, the operating temperature of the faulty electrical component will increase. In this case, more heat is absorbed by the coolant fluid 116 and transferred away from the heat generating component, to be passed to a heat exchanger through a thermal interface. If the heat exchanger cannot remove the heat energy at the rate at which it is absorbed by the coolant fluid 116, the coolant fluid 116 will increase in temperature. This in turn causes the pressure within the cooling module 110 to rise. When the pressure within the cooling module 110 reaches the threshold pressure of the pressure seal 460, the seal opens, allowing the coolant 116 to exit the cooling module 110. At the temperature associated with the threshold pressure, the coolant 116 may be in the gaseous phase, but is at a temperature significantly below that required for chemical breakdown. Accordingly, opening of the pressure valve 460 to depressurise the cooling module 110 and release some of the coolant 116 prevents the continued increase in temperature which could lead to breakdown of the coolant liquid 116. In this way, generation of hazardous chemical breakdown products is avoided.

If, for any reason, the pressure seal 460 fails to open, the coolant can heat to a temperature at which chemical breakdown of the coolant fluid 116 may begin to occur. As a result, at least small amounts of harmful chemical breakdown products such as PFIB or HF can be generated and contained within the cooling module 110. In this case, the chemical breakdown products react with the element 450 having an aluminium oxide coating. This produces further, less hazardous chemical products in place of the PFIB or HF. In one example, the aluminium in the element 450 reacts with the PFIB to generate a less toxic product, and in a second example the aluminium in the element 450 reacts with the HF to produce a less acidic and corrosive product. Accordingly, the element 450 acts to improve the safety of the operation of the cooling system 400 in the event of a fault.

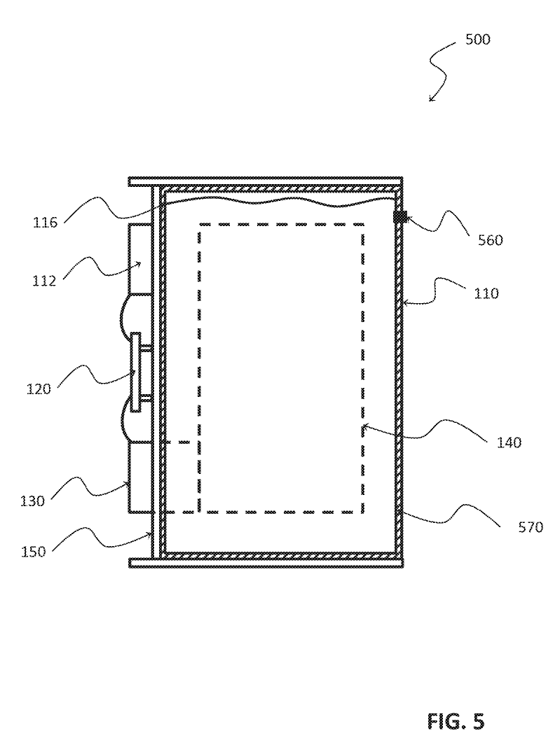

FIG. 5 illustrates a cooling module similar to that discussed above in relation to FIGS. 2 and 3. The cooling system 500 may be slotted or inserted into a cabinet or chassis 20 as illustrated in FIG. 1, and have a rear plate as shown in FIG. 3.

The cooling system 500 comprises a power connector 112, a power regulator 120 and a power input 130 mounted at a rear plate 150 of the cooling module 110. The power input 130 is connected to a circuit board 140, upon which a plurality of heat generating electrical components (not shown) are mounted. The circuit board 140 and heat generating components are immersed in a coolant fluid 116 which contains dissolved oxygen. Cooling of the heat generating components may proceed via convection currents in the coolant fluid 116 as described above in relation to the cooling system of FIG. 1.

The cooling system 500 further comprises an element 570 coating the inner surface of the walls of the cooling module 110. The element or coating 570 is an anodised aluminium layer (accordingly, comprising aluminium oxide). In this case, anodised aluminium layer 570 covers the full inner surface of the walls of the cooling module 110.

In addition, the cooling module comprises a temperature relief seal 560 arranged in the wall of the cooling module 110. The material of the temperature relief seal is selected to soften or melt at a threshold temperature below the temperature at which chemical breakdown of the coolant fluid 116 would occur. The threshold temperature is significantly above the normal operating temperatures of the coolant 116 in the cooling system 500.

In use, if a fault occurs at an electrical component in the cooling module 110, additional heat is transferred to the coolant liquid 116. Where the temperature of the coolant liquid 116 reaches or approaches the threshold temperature of the temperature seal 560, the seal 560 is melted or softened. As a result, a channel into the cooling module 110 is opened. This decreases the pressure within the cooling module 110 may result in release of some coolant fluid 116. As a consequence of the opening of the seal 560, heating of the coolant fluid 116 to the temperature at which chemical breakdown can occur is prevented. Therefore, the seal helps to prevent generation of hazardous chemical breakdown products within the cooling system 110 and offers a further safety feature for the cooling system 500.

If, for any reason, small amounts of hazardous chemical breakdown products (such as PFIB and HF) are produced, the anodised aluminium layer or coating 570 offers a further safety mechanism. The chemical breakdown products of the coolant fluid 116 react with the aluminium based layer 570 to produce further chemical products which are less hazardous. In this way, the element 570 can act as a sacrificial layer for reaction with the hazardous chemical breakdown products.

In a specific example, a perfluoropolyether blend (under the trade name Solvay Galden™), may be used as the coolant fluid 116 within the cooling system 110. Approximately 4 kg of the coolant fluid 116 may be used within a cooling system suitable to be fitted within a server cabinet or chassis 20. In this specific configuration for the cooling module, the temperature seal 560 is expected to breakdown or open at around 150^{C}, with the seal melting at a temperature of around 200^{C}. At around 150^{C} the pressure in the cooling module is around 6 bar, increasing to approximately 16 bar at around 200^{C}. The coolant comprising the specific perfluoropolyether blend described will not begin to chemically break down until a sustained temperature of around 250^{C} is reached.

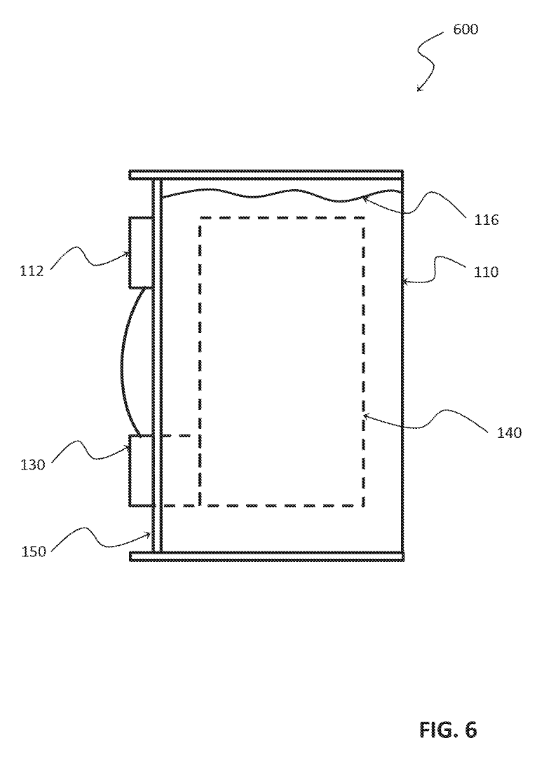

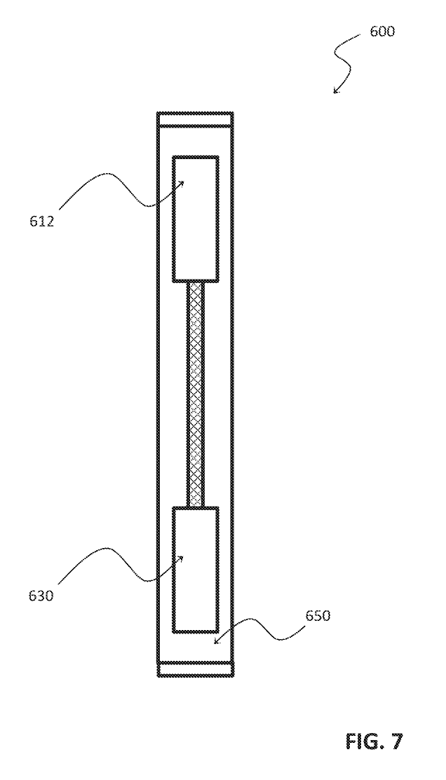

FIGS. 6 and 7 illustrate a cooling system similar to the cooling systems of FIGS. 2, 3, 4 and 5. FIG. 6 illustrates a cross-section through the cooling module, with FIG. 7 showing a view of the rear plate. The cooling module comprises a power connector 112, a power input 130 to the cooling module 110, and a circuit board 140 mounted within the cooling module 110. A plurality of heat generating components (not shown) are arranged on the circuit board 140 and immersed in a coolant 116. The coolant contains dissolved oxygen.

In use, cooling of the heat generating electrical components proceeds by transfer of excess heat to the coolant fluid 116. Heating of the coolant fluid 116 in the vicinity of the heat generating components causes a convention current within the coolant liquid 116 which transfers heat towards a thermal interface with a heat exchanger (not shown). The heat exchanger can then transport the heat away from the cooling system 600. Within the cooling module 110, in normal operation the coolant 116 remains in the liquid phase and does not boil. All circulation of the coolant liquid 116 within the cooling module 110 takes place via convention currents, and the coolant 116 is not pumped.

In the event of a fault occurring at a heat generating component in the cooling module 110, the coolant liquid 116 may receive heat at a rate faster than the heat can be transferred to the heat exchanger and out of the system. As a result the coolant fluid 116 temperature will increase. Eventually, the coolant fluid 116 will heat to a temperature at which the dissolved oxygen is released or liberated from the coolant 116. The released oxygen gas can then react with the heat generating components to oxidise at least a portion of the component. A heat generating component operating at a higher temperature may be more susceptible to oxidation.

As a result of oxidation, the heat generated by the heat generating component is reduced. For example, the oxidation may cause an increase in the resistance of the electrical input to the heat generating component. The resistance increase results from a decreased area through which current can be carried as a consequence of the oxidation. An increase in resistance may reduce the current drawn by the electrical component, and so its operating temperature. In some circumstances, the increased resistance may cause the component to “fuse”, breaking the electrical connection of the heat generating component.

Accordingly, use of a coolant fluid 116 comprising dissolved oxygen provides a method of halting a runaway increase of temperature of the coolant liquid 116. Consequently, the use of dissolved oxygen in the coolant liquid 116 reduces the likelihood of chemical breakdown of the coolant fluid 116 into hazardous chemical breakdown products (for example, such as PFIB or HF).

At least four mechanisms for improving the safety of operation of a cooling system have been described herein. Each of these mechanisms may be used independently or in any combination to improve the overall safety of operation of a cooling system.

Specifically these four mechanisms include:
a) Use of a power regulator to regulate the power supplied into the cooling module of the cooling system. The power being regulated such that the excess energy is maintained below the energy input threshold of a coolant within the cooling module required to undergo chemical breakdown.
b) Use of an aluminium or aluminium oxide element (such as an anodised aluminium layer or an aluminium component) within the volume of the cooling module to react with at least some chemical breakdown products of the coolant fluid. After the reaction of the chemical breakdown products with the element, the resultant products may be less hazardous or less acidic.
c) Use of a coolant comprising dissolved oxygen. The dissolved oxygen may be liberated or released from the coolant if the coolant liquid is heated above a certain temperature. The released oxygen may react with a portion of an electrical component or component within the cooling module to at least partially oxidise the component. For example, the electrical input to a heat generating component may be oxidised such that the resistance of an electrical current to the heat generating component is greatly increased. The increased resistance may cause the component to fuse. As a result, the excessive heating of the heat generating component is halted.
d) Use of a temperature or pressure relief seal to vent the cooling module before a pressure and temperature is reached that could result in chemical breakdown of the coolant fluid within the cooling module.

Many combinations, modifications, or alterations to the features of the above embodiments will be readily apparent to the skilled person and are intended to form part of the invention. Any of the features described specifically relating to one embodiment or example may be used in any other embodiment by making the appropriate changes.

For example, in the specific examples discussed above in relation to FIGS. 2 and 3, the power regulator is either a voltage regulator or a voltage regulator and a fully isolated DC-DC converter connected in series. However, the power regulator may be any electrical component or circuit which acts to stabilise or control the power input to the cooling module (and in particular, to the electrical components at the circuit board within the cooling module). As would be understood by the skilled person, a power regulator could comprise circuitry for voltage regulation, current regulation, current limitation, voltage limitation, or any combination of these components.

In FIGS. 2 and 3 discussed above, the power regulator is arranged to be attached to the rear plate of the cooling module and so external to the cooling module. In the example shown, the rear plate is the surface of the cooling module received by the cabinet or chassis and upon which the power connector to the cabinet or chassis is mounted. However, in another example the power regulator could be arranged at a different position or on a different surface of the cooling module whilst being kept external to the cooling module. In a still further example, the power regulator could be arranged at the cabinet or chassis but in series with the power input to the cooling module. In either case, all electrical connections to the electrical components are routed through the power regulator. In most cases, the power regulator will be directly adjacent the power input, such that the power regulator and power input are arranged in series as neighbouring components in the electrical circuit. Ideally, a particular power regulator acts exclusively to regulate the power entering a particular single cooling system or cooling fin.

Although each of the embodiments described above are described as using a coolant containing dissolved oxygen, a coolant that has been degassed or without dissolved oxygen could be used within the illustrated cooling systems. Alternatively, a coolant fluid containing any dissolved gas comprising oxygen may be used. In particular, the dissolved oxygen could be dissolved in the coolant in the form of “pure” oxygen. Alternatively, the dissolved oxygen could be provided as a component of a dissolved gas having more than 21% oxygen by volume (in other words, a dissolved gas comprising an oxygen content more than that of air). For example, the oxygen content of the dissolved gas may be 25% or more, 50% or more, or 75% or more. Pure oxygen may have an oxygen content of more than 99%.

In the embodiment of FIG. 4, the element is a separate element having an aluminium oxide coating. FIG. 5 shows the element being a coating on the inner surface of the walls of the cooling module. However, in other examples the element may take different forms. For example, the element may be a sacrificial element comprised only of aluminium or aluminium oxide, or the element may be as a coating on the heat transfer surface or thermal interface (not shown).

In the specific embodiment discussed above in relation to FIG. 5, the coolant fluid is perfluoropolyether, PFPE (for instance Solvay Galden™). The particular pressures and temperatures recited in relation to FIG. 5 for opening of the temperature seal are provided specifically for perfluoropolyether and a cooling system having a size to fit within an Iceotope Limited chassis or server cabinet. However, other types of coolant could be used, or the volume of the cooling module may be a different size. In this situation the appropriate threshold temperatures and pressures for a temperature or pressure seal should be chosen. As an example, coolant fluids containing fluoro-octanes (for instance Fluorinert™), HFE (for instance Novec™), hydrofluorolefin, HFO (for instance Vertrel Sinara™), perfluoroketone, PFK (for instance by Novec™) could also be used. Each of these coolant fluids demonstrates similar boiling temperatures. However, some may have a lower chemical breakdown temperature (for example, HFE/PFK by Novec™ can begin to breakdown at around 150^{C} compared to a breakdown temperature of 250^{C} for perfluoropolyether by Solvay Galden™). Accordingly, use of Novec™ would require an appropriate selection of threshold pressure and temperature for a pressure or temperature seal. For example, a different material could be selected for use within the seal. The seals should also be selected for materials compatibility and permeability with the coolant fluid.

1. A cooling system for cooling of a heat generating electrical component, comprising:
a coolant liquid to absorb excess energy from the heat generating electrical component, wherein the coolant liquid has an energy input threshold above which chemical breakdown of the coolant liquid occurs;
a cooling module defining a volume containing the coolant liquid, the heat generating electrical component mounted within the volume and immersed in the coolant liquid;
a power input arranged to supply power into the cooling module to energise the heat generating electrical component; and
a power regulator, external to the volume of the cooling module and connected to the power input, the power regulator configured to regulate the power supplied into the cooling module such that the excess energy is maintained below the energy input threshold.

2. The cooling system according to claim 1, wherein the power regulator comprises at least one or a combination of the following elements: a voltage regulator, a current regulator, a DC-DC converter, a voltage limiter, a current limiter.

3. The cooling system according to claim 1, wherein the power regulator is arranged at an outer surface of the cooling module.

4. The cooling system according to claim 1, wherein the power regulator is air cooled.

5. The cooling system according to claim 1, wherein the power regulator is thermally connected to a thermally conductive outer surface of the cooling module, such that the outer surface acts as a heat sink to conduct heat away from the power regulator.

6. The cooling system according to claim 5, wherein the thermally conductive outer surface is thermally connected to the coolant liquid such that heat is exchanged with the coolant liquid to cool the thermally conductive outer surface.

7. The cooling system according to claim 1, wherein the power regulator regulates the power supplied to the heat generating electrical component so that the maximum supplied power is substantially constant, the magnitude of the substantially constant maximum supplied power determined according to the power rating of the heat generating electrical component.

8. The cooling system according to claim 7, wherein the magnitude of the substantially constant supplied power matches the power rating of the heat generating electrical component.

9. The cooling system according to claim 1, wherein the power regulator regulates the power supplied to the heat generating electrical component to be within ±30% of the power rating of the heat generating electrical component.

10. The cooling system according to claim 1, wherein the power regulator limits the power supplied to the heat generating electrical component to less than a predetermined limit of 200% of the maximum power rating of the heat generating electrical component.

11. The cooling system according to claim 1, wherein all power received at the heat generating electrical component is passed through the power regulator.

12. The cooling system according to claim 1, wherein the power regulator is a first power regulator, and the cooling system further comprises a second power regulator.

13. The cooling system according to claim 12, wherein the first power regulator is arranged external to the cooling module, and the second power regulator is arranged within the sealed volume of the cooling module.

14. (canceled)

15. (canceled)

16. The cooling system according to claim 1, wherein the coolant liquid comprising dissolved oxygen.

17. The cooling system according to claim 1, wherein an element comprising aluminium or aluminium oxide is arranged within the volume of the cooling module.

18. The cooling system according to claim 17, wherein the aluminium or aluminium oxide element is a coating comprising aluminium or aluminium oxide, the coating arranged on at least a portion of an inner surface of the cooling module, the inner surface defining the volume.

19. (canceled)

20. The cooling system according to claim 1, wherein the volume is sealed and the cooling module further comprises a pressure release seal arranged to open the sealed volume of the cooling module when the pressure inside the sealed volume exceeds a threshold pressure.

21. The cooling system according to claim 1, wherein the volume is sealed, and the cooling module further comprises a temperature release seal arranged to open the sealed volume of the cooling module when the temperature inside the sealed volume exceeds a threshold temperature.

22. The cooling system of claim 1, the cooling module further comprising a thermal interface arranged to transfer out of the volume the heat generated by the heat generating electrical component, the heat from the heat generating electrical component being absorbed by the coolant liquid and transported to the thermal interface via a convective current.

23. The cooling system of claim 22, the cooling system further comprising a heat exchanger, arranged to receive heat from the thermal interface and to transport the heat away from the cooling module.

24-66. (canceled)
